(19) United States
(12) Patent Application Publication
(10) Pub. No.: US 2017/0162519 A1
(43) Pub. Date: Jun. 8, 2017

(54) SEMICONDUCTOR DEVICE AND MANUFACTURING METHOD THEREOF

(71) Applicant: Amkor Technology, Inc., Tempe, AZ (US)

(72) Inventors: Yeong Beom Ko, Gwangju (KR); Jae Jin Lee, Seoul (KR); Kwang Seok Oh, Seongnam-si (KR)

(21) Appl. No.: 15/149,231

(22) Filed: May 9, 2016

(30) Foreign Application Priority Data
Dec. 4, 2015 (KR) 10-2015-0172532

(51) Int. Cl. H01L 23/00; H01L 23/31; H01L 21/78; H01L 23/373; H01L 21/48; H01L 21/56

(52) U.S. Cl. CPC H01L 23/562; H01L 21/4882; H01L 21/565; H01L 21/78; H01L 24/02; H01L 24/13; H01L 23/3736; H01L 23/3114; H01L 2224/02315; H01L 2224/02331; H01L 2224/02377; H01L 2224/0239; H01L 2224/13024; H01L 2924/3511

(57) ABSTRACT

A semiconductor device and a method of manufacturing a semiconductor package. As a non-limiting example, various aspects of this disclosure provide a method of manufacturing a semiconductor package, and a semiconductor package resulting therefrom, that comprises attaching at least one semiconductor die to a metal plate, encapsulating the at least one semiconductor die on the metal plate using an encapsulant, and dicing the metal plate and the encapsulant.

### CROSS-REFERENCE TO RELATED APPLICATIONS/INCORPORATION BY REFERENCE

The present application makes reference to, claims priority to, and claims the benefit of Korean Patent Application No. 10-2015-0172532, filed on Dec. 4, 2015, in the Korean Intellectual Property Office and titled “SEMICONDUCTOR DEVICE,” the contents of which are hereby incorporated herein by reference in their entirety.

### BACKGROUND

Present semiconductor devices and methods for manufacturing semiconductor devices are inadequate, for example resulting in excess cost, decreased reliability, or package sizes that are too large. Further limitations and disadvantages of conventional and traditional approaches will become apparent to one of skill in the art, through comparison of such approaches with the present disclosure as set forth in the remainder of the present application with reference to the drawings.

### BRIEF DESCRIPTION OF SEVERAL VIEWS OF THE DRAWINGS

FIG. 1 is a flowchart illustrating a method for manufacturing a semiconductor package, according to an embodiment of the present disclosure.

FIGS. 2A to 2E are cross-sectional views illustrating a method for manufacturing a semiconductor package, according to an embodiment of the present disclosure.

FIGS. 3A to 3D are cross-sectional views illustrating a method for manufacturing a semiconductor package, according to another embodiment of the present disclosure.

### SUMMARY

Various aspects of this disclosure provide a semiconductor package and a method of manufacturing a semiconductor device. As a non-limiting example, various aspects of this disclosure provide a method of manufacturing a semiconductor package, and a semiconductor package resulting therefrom, that comprises attaching at least one semiconductor die to a metal plate, encapsulating the at least one semiconductor die on the metal plate using an encapsulant, and dicing the metal plate and the encapsulant.

### DETAILED DESCRIPTION OF VARIOUS ASPECTS OF THE DISCLOSURE

The following discussion presents various aspects of the present disclosure by providing examples thereof. Such examples are non-limiting, and thus the scope of various aspects of the present disclosure should not necessarily be limited by any particular characteristics of the provided examples. In the following discussion, the phrases “for example,” “e.g.,” and “exemplary” are non-limiting and are generally synonymous with “by way of example and not limitation,” “for example and not limitation,” and the like.

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.”

The terminology used herein is for the purpose of describing particular examples only and is not intended to be limiting of the disclosure. As used herein, the singular forms are intended to include the plural forms as well, unless the context clearly indicates otherwise. It will be further understood that the terms “comprises,” “includes,” “comprising,” “including,” “has,” “have,” “having,” and the like when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure. Similarly, various spatial terms, such as “upper,” “above,” “lower,” “below,” “side,” and the like, may be used in distinguishing one element from another element in a relative manner. It should be understood, however, that components may be oriented in different manners, for example a semiconductor device may be turned sideways so that its “top” surface is facing horizontally and its “side” surface is facing vertically, without departing from the teachings of the present disclosure.

In the drawings, the thickness or size of layers, regions, and/or components may be exaggerated for clarity. Accordingly, the scope of this disclosure should not be limited by such thickness or size. Additionally, in the drawings, like reference numerals may refer to like elements throughout the discussion.

It will also be understood that when an element A is referred to as being “connected to” or “coupled to” an element B, the element A can be directly connected to the element B or indirectly connected to the element B (e.g., an intervening element C (and/or other elements) may be present between the element A and the element B).

Various aspects of the present disclosure relates to a semiconductor device and a manufacturing method thereof.

Certain embodiments of the disclosure relate to a method for fabricating a semiconductor package and a semiconductor package using the same.

Recently, with the trend toward smaller and lighter terminals for mobile communication, such as a cellular phone or a smart phone, or small-sized electronic devices, such as a tablet PC, a notebook PC, a MP3 player, or a digital camera, semiconductor packages constructing the small-sized electronic devices are also becoming smaller and lighter in weight. According to the miniaturization of electronic products, methods for reducing sizes of the semiconductor packages are being intensively researched. However, mechanical strengths of products may be compromised and it may also be difficult to support a semiconductor die by focusing on the miniaturization of products.

Embodiments of the present disclosure provide a method for fabricating a semiconductor package and a semiconductor package using the same, which can improve reliability of the package while reducing warpage.

According to an aspect of the present disclosure, there is provided a method for fabricating a semiconductor package, the method including preparing at least one semiconductor die having a conductive bump formed on its top surface, attaching the at least one semiconductor die to a metal plate, encapsulating the at least one semiconductor die on the metal plate using an encapsulant, and dicing the metal plate and the encapsulant to fabricate the semiconductor package.

According to another aspect of the present disclosure, there is provided a semiconductor package using the method for fabricating a semiconductor package, the semiconductor package including a semiconductor die having a conductive bump formed on its top surface, a metal plate formed under the semiconductor die, and an encapsulant encapsulating the semiconductor die on the metal plate.

Various advantages, aspects and novel features of the present disclosure, as well as details of an illustrated embodiment thereof, will be more fully understood from the following description and drawings.

Hereinafter, examples of embodiments of the disclosure will be described in detail with reference to the accompanying drawings such that they can readily be made and used by those skilled in the art.

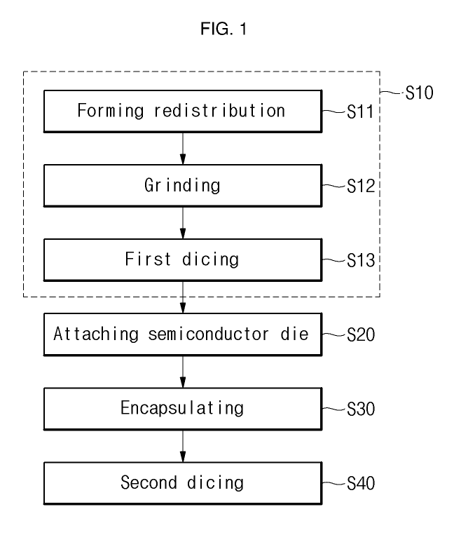

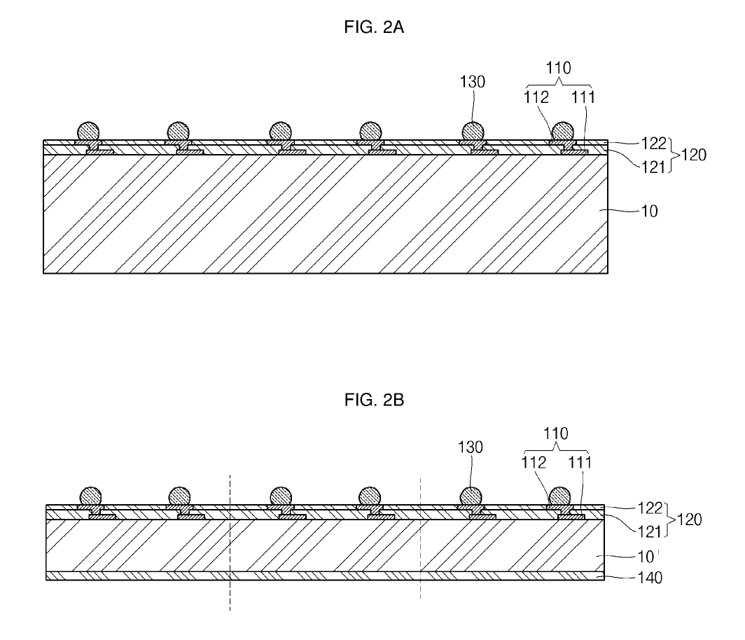

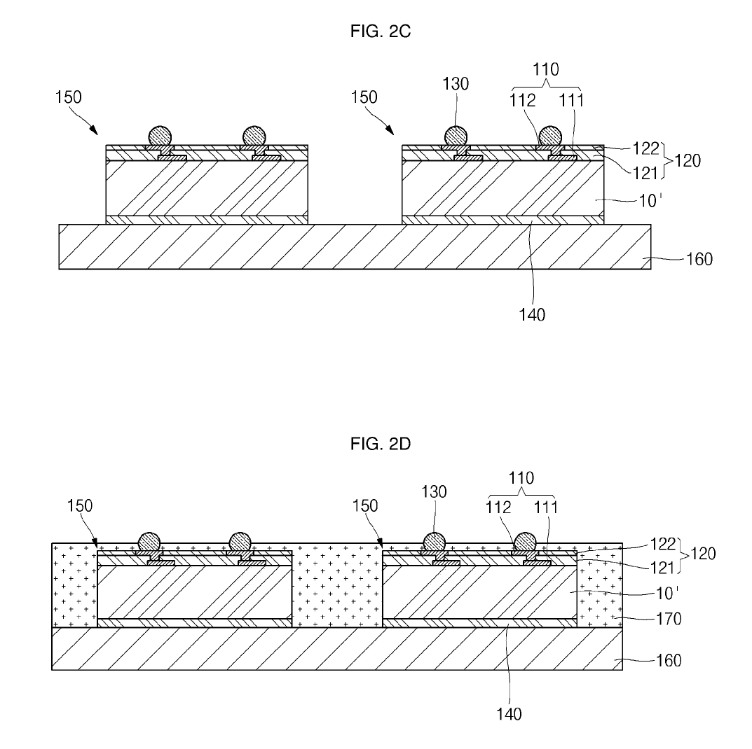

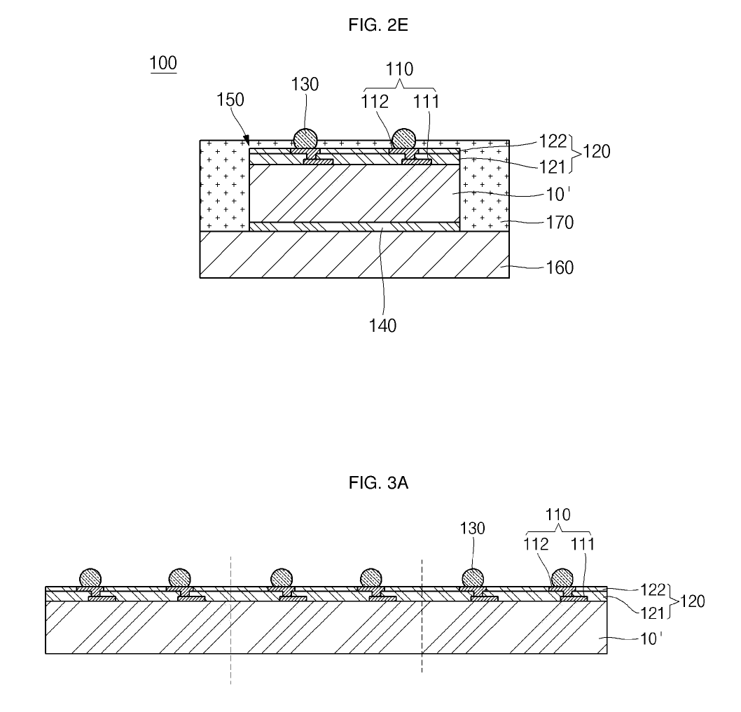

FIG. 1 is a flowchart illustrating a method for fabricating a semiconductor package according to an embodiment of the present disclosure, and FIGS. 2A to 2E are cross-sectional views illustrating a method for manufacturing (or fabricating) a semiconductor package according to an embodiment of the present disclosure.

Referring to FIG. 1, the method for manufacturing (or fabricating) a semiconductor package according to an embodiment of the present disclosure includes forming a redistribution layer (S11), grinding (S12), first dicing (S13), attaching a semiconductor die (S20), encapsulating (S30) and second dicing (S40). Here, the forming of a redistribution layer (S11), the grinding (S12) and the first dicing (S13) may be defined as the step of preparing a semiconductor die (S10). Hereinafter, various steps of FIG. 1 will be described with reference to FIGS. 2A to 2E.

In the preparing of the semiconductor die (S10), the semiconductor die 150 as a basic element of the semiconductor package according to an embodiment of the present disclosure is prepared. In detail, the preparing of the semiconductor die (S10) includes forming a redistribution layer (S11), grinding (S12) and first dicing (S13).

In the forming of the redistribution layer (S11), the redistribution layer 110 is formed on the wafer 10. Note that the redistribution layer 110 may also be referred to herein as a redistribution structure. As illustrated in FIG. 2A, in the forming of the redistribution layer (S11), the redistribution layer 110 having a multi-layered structure and a dielectric layer 120 (e.g., one or more dielectric layers) covering the redistribution layer 110 (e.g., covering one or more conductive layers thereof) are formed on the wafer 10. As an example, a first redistribution layer 111 is formed on the wafer 10 and a portion of the first redistribution layer 111 is covered by a first dielectric layer 121. Note that the first redistribution layer 111 may also be referred to herein as a conductive layer. In addition, a second redistribution layer 112 electrically connected to the first redistribution layer 111 is further formed and a portion of the second redistribution layer 112 is covered by a second dielectric layer 122, thereby forming the redistribution layer 110 having a multi-layered structure. Note that the second redistribution layer 112 may also be referred to herein as a conductive layer. In the illustrated embodiment, the redistribution layer 110 has a two-layered structure, but aspects of the present disclosure are not limited thereto. Rather, the redistribution layer 110 may include more than or less than two layers. In addition, the wafer 10 may be made of silicon (Si), glass or a metal, but aspects of the present disclosure are not limited thereto.

The redistribution layer 110 (e.g., one or more conductive layers thereof) may be made of one selected from the group consisting of copper, aluminum, gold, silver, palladium and equivalents thereof using electroless plating, electroplating and/or sputtering, but aspects of the present disclosure are not limited to such materials and/or processes. In addition, patterning or routing of the first redistribution layer 111 and/or second redistribution layer 112 may be performed by photolithography using a photoresist, but aspects of the present disclosure are not limited thereto.

The dielectric layer 120 may be made of one selected from the group consisting of oxide, nitride, polyimide, benzocyclobutene, polybenzoxazole, bismaleimide triazine (BT), phenol resin, epoxy, and equivalents thereof, but aspects of the present disclosure are not limited thereto. In addition, the dielectric layer 120 may be formed by one selected from the group consisting of spin coating, spray coating, dip coating, rod coating, chemical vapor deposition (CVD) and equivalents thereof, but aspects of the present disclosure are not limited thereto.

In addition, in the forming of the redistribution layer (S11), after forming the redistribution layer 110, the conductive bump 130 may be formed on the redistribution layer 110. The conductive bump 130 may be formed on the second redistribution layer 112 exposed to the outside by the second dielectric layer 122. The conductive bump 130 may be made of a eutectic solder (Sn37Pb), a high lead solder (Sn95Pb), a lead-free solder (SnAg, SnAu, SnCu, SnZn, SnZnBi, SnAgCu, or SnAgBi), and equivalents thereof, but aspects of the present disclosure are not limited thereto. In addition, the conductive bump 130 may be formed on the redistribution layer 110 by a reflow process, a solder ball drop process and/or an equivalent thereof, but aspects of the present disclosure are not limited thereto. As an example, the conductive bump 130 may include a solder ball, a conductive pillar such as a copper pillar, and/or a conductive post having a solder cap formed on a copper pillar.

In the grinding (S12), a bottom surface of the wafer 10 is grinded. As illustrated in FIG. 2B, in the grinding (S12), the bottom surface of the wafer 10 is grinded, thereby removing a portion of the wafer 10. Here, the grinding may be performed by, for example, a diamond grinder and/or an equivalent thereof, but aspects of the present disclosure are not limited thereto. In addition, an adhesive member 140 is attached to the grinded bottom surface of the wafer 10′. The adhesive member 140 supports the wafer 10′ having the grinded bottom surface, thereby facilitating handling of subsequent processes. That is to say, if the bottom surface of the wafer 10 is grinded, the wafer 10′ may have a reduced thickness to then reduce the size of the package, making it difficult to handle the wafer 10′. In the present disclosure, however, the relatively thin wafer 10′ can be supported by attaching the adhesive member 140 to the bottom surface of the wafer 10, thereby facilitating the handling of subsequent processes. In addition, the adhesive member 140 may serve to attach the semiconductor die 150 to the metal plate 160 after forming the semiconductor die 150 by dicing the wafer 10′ in a subsequent step. The adhesive member 140 may be formed as a film-type adhesive tape, which is also called a die attach film (DAF). Of course, the adhesive member 140 may be generally made of an epoxy adhesive, but the scope of the present disclosure is not limited thereto.

In the first dicing (S13), the wafer 10′ is diced to fabricate an individual semiconductor die 150. In the first dicing (S13), the wafer 10′ may be diced along dotted lines, as illustrated in FIG. 2B, thereby completing the individual semiconductor die 150, as illustrated in FIG. 2C. In the first dicing (S13), the wafer 10′ may be diced by a diamond blade or laser beam, but aspects of the present disclosure are not limited thereto. The semiconductor die 150 may possess characteristics of various types of semiconductor dies. For example, the semiconductor die 150 may include a processor die, a memory die, an application specific integrated circuit (ASIC) die, a general logic die, active semiconductor components, and so on.

In the attaching of the semiconductor die (S20), the semiconductor die 150 is attached to the metal plate 160. As illustrated in FIG. 2C, in the attaching of the semiconductor die (S20), at least one semiconductor die 150 may be attached to the metal plate 160. That is to say, in the attaching of the semiconductor die (S20), a plurality of semiconductor dies 150 may be attached to the metal plate 160. Here, the adhesive member 140 formed under the semiconductor die 150 is brought into contact with the metal plate 160. That is to say, the semiconductor die 150 may be attached to the metal plate 160 using the adhesive member 140.

The metal plate 160 is shaped of a flat plate made of a metal. The metal plate 160 may be made of one selected from the group consisting of stainless steel (SUS), copper, aluminum, and equivalents thereof, but the scope of the present disclosure is not limited thereto. The metal plate 160 is preferably made of stainless steel (SUS). Here, the stainless steel (SUS) refers to a kind of steel including at least 11% chrome added to iron to reinforce corrosion resistance. In addition, the stainless steel (SUS) is classified into various types according to contents of chrome, nickel, molybdenum, etc. As an example, the stainless steel (SUS) may be exemplified as SUS201, SUS303, SUS303Se, SUS304, SUS304L, SUS305, SUS309S, SUS310S, SUS316, SUS316L, SUS317, SUS317L, SUS312, SUS321, SUS347, SUS409L, SUS410L, SUS430, SUS434, SUS436L, SUS444, and so on, but aspects of the present disclosure are not limited thereto. The metal plate 160 may serve to reinforce mechanical strength of the semiconductor die 150 while rapidly emitting heat generated from the semiconductor die 150 to the outside. In addition, the metal plate 160 is capable of preventing the semiconductor package from shrinking at high temperature and can reduce a warpage phenomenon occurring during fabrication of the semiconductor package, thereby improving reliability of the semiconductor package.

In the encapsulating (S30), an encapsulant 170 encapsulates the semiconductor die 150 positioned on the metal plate 160. As illustrated in FIG. 2D, the encapsulant 170 completely encapsulates the semiconductor die 150, thereby protecting the semiconductor die 150 against damages due to external impacts and oxidation. The encapsulant 170 encapsulates side surfaces of the semiconductor die 150 and a top surface of the semiconductor die 150 having the conductive bump 130 formed thereon. That is to say, the encapsulant 170 is formed to cover a portion of the conductive bump 130. As described above, since the side and top surfaces of the semiconductor die 150 are entirely covered by the encapsulant 170, an insulating property and board-level reliability can be improved and mechanical damages, such as chipping, can be prevented. In the encapsulating (S30), compression molding, vacuum molding, or transfer molding may be employed, but aspects of the present disclosure are not limited thereto. In addition, the encapsulant 170 may be one selected from the group consisting of a thermocurable epoxy molding compound (EMC), room-temperature curable glop top for dispensing, and an equivalent thereof, but aspects of the present disclosure are not limited thereto.

In the second dicing (S40), the metal plate 160 and the encapsulant 170 are diced. As illustrated in FIG. 2E, in the second dicing (S40), the metal plate 160 and the encapsulant 170 are diced, thereby completing a semiconductor package 100 according to various aspects of the present disclosure. In the second dicing (S40), the metal plate 160 and the encapsulant 170 may be diced using a diamond blade or laser beam, but aspects of the present disclosure are not limited thereto.

The semiconductor package 100 fabricated by the method according to the present disclosure includes the semiconductor die 150 having the conductive bump 130 formed on its top surface, the metal plate 160 formed under the semiconductor die 150, the adhesive member 140 interposed between the semiconductor die 150 and the metal plate 160, and the encapsulant 170 encapsulating the semiconductor die 150 on the metal plate 160.

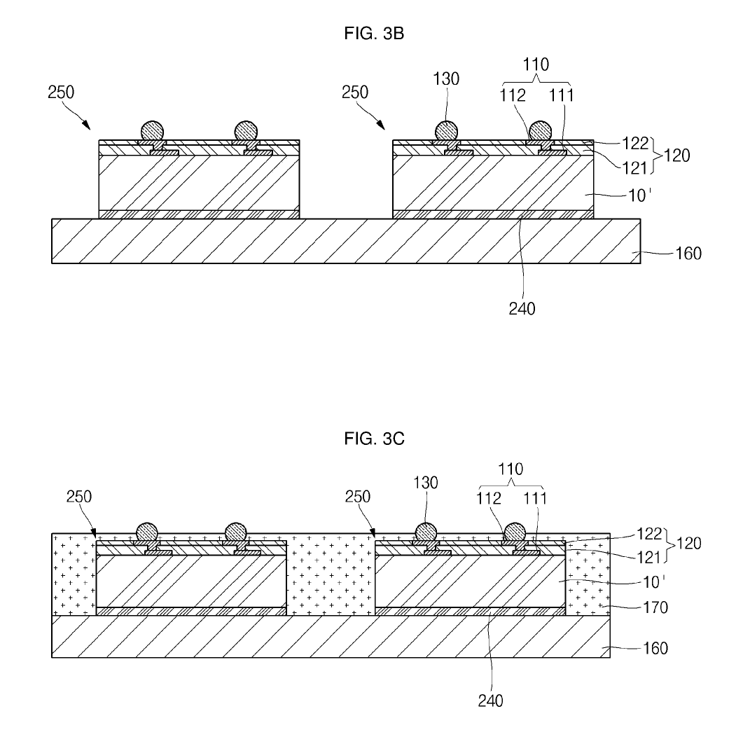

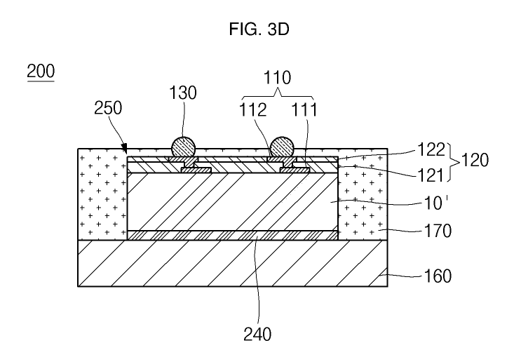

FIGS. 3A to 3D are cross-sectional views illustrating a method for fabricating a semiconductor package according to another embodiment of the present disclosure.

Referring to FIG. 1, the method for fabricating a semiconductor package according to another embodiment of the present disclosure includes forming a redistribution layer (S11), grinding (S12), first dicing (S13), attaching a semiconductor die (S20), encapsulating (S30) and second dicing (S40). The method for fabricating a semiconductor package according to another embodiment of the present disclosure is substantially the same as the semiconductor package fabricating method illustrated in FIGS. 2A to 2E, and the following description will focus on differences between the semiconductor packages according to the present and previous embodiments of the present disclosure. Hereinafter, various steps of FIG. 1 will be described with reference to FIGS. 3A to 3D.

In the forming of the redistribution layer (S11), a redistribution layer 110 (or redistribution structure) having a multi-layered structure and a dielectric layer 120 covering the redistribution layer 110 are formed on a wafer 10. Since the forming of the redistribution layer (S11) is the same as that illustrated in FIG. 2A, a detailed description will not be given.

In the grinding (S12), a bottom surface of the wafer 10 is grinded. As illustrated in FIG. 3A, in the grinding (S12), the bottom surface of the wafer 10 is grinded, thereby removing a portion of the wafer 10. Here, the grinding may be performed by, for example, a diamond grinder and/or an equivalent thereof, but aspects of the present disclosure are not limited thereto. Unlike in FIG. 2B, in the grinding (S12), an adhesive member is not attached to the grinded bottom surface of the wafer 10′.

In the first dicing (S13), the wafer 10′ is diced to fabricate an individual semiconductor die 250. In the first dicing (S13), the wafer 10′ may be diced along dotted lines, as illustrated in FIG. 3A, thereby completing the individual semiconductor die 250, as illustrated in FIG. 3B. In the first dicing (S13), the wafer 10′ may be diced by a diamond blade or laser beam, but aspects of the present disclosure are not limited thereto. The semiconductor die 250 may possess characteristics of various types of semiconductor dies. For example, the semiconductor die 250 may include a processor die, a memory die, an application specific integrated circuit (ASIC) die, a general logic die, active semiconductor components, and so on.

In the attaching of the semiconductor die (S20), as illustrated in FIG. 3B, the semiconductor die 250 is attached to the metal plate 160. In the attaching of the semiconductor die (S20), at least one semiconductor die 250 may be attached to the metal plate 160 using an adhesive member 240. In the attaching of the semiconductor die (S20), the adhesive member 240 may be formed on the metal plate 160 and the semiconductor die 250 may be attached to the metal plate 160. That is to say, the semiconductor die 250 may be attached to the metal plate 160 using the adhesive member 240. For example, the adhesive member 240 made of a liquid-type epoxy is coated on the metal plate 160, the semiconductor die 250 is placed on the adhesive member 240, followed by curing the adhesive member 240, thereby attaching the semiconductor die 250 to the metal plate 160. In addition, the adhesive member 240 formed on only a region to which the semiconductor die 150 is attached is illustrated, but aspects of the present disclosure are not limited thereto. Rather, the adhesive member 240 may be entirely formed on a top surface of the metal plate 160. However, in the encapsulating (S30) to be described later, in order to attain a secured coupling force between the encapsulant 170 and the metal plate 160, the adhesive member 240 is preferably formed on only the region where the semiconductor die 250 is attached. The adhesive member 240 may be formed as a general liquid epoxy adhesive or a film-type adhesive tape, but aspects of the present disclosure are not limited thereto.

The metal plate 160 is shaped of a flat plate made of a metal. The metal plate 160 may be made be made of one selected from the group consisting of stainless steel (SUS), copper, aluminum, and equivalents thereof. The metal plate 160 is preferably made of stainless steel (SUS). The metal plate 160 may serve to reinforce mechanical strength of the semiconductor die 250 while rapidly emitting heat generated from the semiconductor die 250 to the outside. In addition, the metal plate 160 is capable of preventing the semiconductor package from shrinking at high temperature and can reduce a warpage phenomenon occurring during fabrication of the semiconductor package, thereby improving reliability of the semiconductor package.

In the encapsulating (S30), an encapsulant 170 encapsulates the semiconductor die 250 positioned on the metal plate 160. As illustrated in FIG. 3C, the encapsulant 170 completely encapsulates the semiconductor die 250, thereby protecting the semiconductor die 250 against damages due to external impacts and oxidation. The encapsulant 170 encapsulates side surfaces of the semiconductor die 250 and a top surface of the semiconductor die 250 having the conductive bump 130 formed thereon. That is to say, the encapsulant 170 is formed to cover a portion of the conductive bump 130. As described above, since the side and top surfaces of the semiconductor die 250 are entirely covered by the encapsulant 170, an insulating property and board-level reliability can be improved and mechanical damages, such as chipping, can be prevented. In the encapsulating (S30), compression molding, vacuum molding, or transfer molding may be employed, but aspects of the present disclosure are not limited thereto. In addition, the encapsulant 170 may be one selected from the group consisting of a thermocurable epoxy molding compound (EMC), room-temperature curable glop top for dispensing, and an equivalent thereof, but aspects of the present disclosure are not limited thereto.

In the second dicing (S40), the metal plate 160 and the encapsulant 170 are diced. As illustrated in FIG. 3D, in the second dicing (S40), the metal plate 160 and the encapsulant 170 are diced, thereby completing a semiconductor package 200 according to the present disclosure. In the second dicing (S40), the metal plate 160 and the encapsulant 170 may be diced using a diamond blade or laser beam, but aspects of the present disclosure are not limited thereto.

The semiconductor package 200 fabricated by the method according to the present disclosure includes the semiconductor die 250 having the conductive bump 130 formed on its top surface, the metal plate 160 formed under the semiconductor die 250, the adhesive member 240 interposed between the semiconductor die 250 and the metal plate 160, and the encapsulant 170 encapsulating the semiconductor die 250 on the metal plate 160

The discussion herein included numerous illustrative figures that showed various portions of an electronic device assembly and method of manufacturing thereof. For illustrative clarity, such figures did not show all aspects of each example assembly. Any of the example assemblies and/or methods provided herein may share any or all characteristics with any or all other assemblies and/or methods provided herein.

In summary, various aspects of this disclosure provide a semiconductor package and a method of manufacturing a semiconductor device. As a non-limiting example, various aspects of this disclosure provide a method of manufacturing a semiconductor package, and a semiconductor package resulting therefrom, that comprises attaching at least one semiconductor die to a metal plate, encapsulating the at least one semiconductor die on the metal plate using an encapsulant, and dicing the metal plate and the encapsulant. While the foregoing has been described with reference to certain aspects and examples, it will be understood by those skilled in the art that various changes may be made and equivalents may be substituted without departing from the scope of the disclosure. In addition, many modifications may be made to adapt a particular situation or material to the teachings of the disclosure without departing from its scope. Therefore, it is intended that the disclosure not be limited to the particular example(s) disclosed, but that the disclosure will include all examples falling within the scope of the appended claims.

What is claimed is:

1. A method of manufacturing a semiconductor package, the method comprising:
preparing a semiconductor die having a top die surface, a bottom die surface and side die surfaces, and comprising a conductive bump on the top die surface;
attaching the bottom die surface to a metal plate;
encapsulating the semiconductor die on the metal plate using an encapsulant; and
dicing the metal plate and the encapsulant.

2. The method of claim 1, wherein said encapsulating comprises encapsulating the top die surface and the side die surfaces.

3. The method of claim 2, wherein said encapsulating comprises encapsulating at least a portion of the conductive bump.

4. The method of claim 1, wherein said preparing the semiconductor die comprises:
forming a redistribution structure on a top surface of a wafer, wherein the redistribution structure comprises at least one conductive layer and at least one dielectric layer;
forming the conductive bump on a top surface of the redistribution structure;
grinding a bottom surface of the wafer; and
dicing the wafer.

5. The method of claim 4, comprising after said grinding the bottom surface of the wafer and before said dicing the wafer, forming an adhesive layer on the ground bottom surface of the wafer.

6. The method of claim 4, wherein said encapsulating comprises encapsulating the at least one dielectric layer.

7. The method of claim 1, wherein said attaching the bottom die surface to the metal plate comprises attaching the bottom die surface to the metal plate with an adhesive tape.

8. The method of claim 1, wherein said attaching the bottom die surface to the metal plate comprises:
forming an adhesive layer on the metal plate;
and placing the bottom die surface on the adhesive layer.

9. The method of claim 1, wherein the metal plate comprises stainless steel.

10. A method of manufacturing a semiconductor package, the method comprising:
forming a redistribution structure on a top surface of wafer, where the redistribution structure comprises at least one conductive layer and at least one dielectric layer;
grinding a bottom surface of the wafer;
forming an adhesive layer on the ground bottom surface of the wafer;
dicing the wafer, redistribution layer, and adhesive layer to form a die having a top die surface, a bottom die surface and side die surfaces;
attaching the bottom die surface to a metal plate;
encapsulating the semiconductor die on the metal plate using an encapsulant; and
dicing the metal plate and the encapsulant.

11. The method of claim 10, comprising prior to said dicing the wafer, forming a conductive bump on a top surface of the redistribution structure.

12. The method of claim 11, wherein said encapsulating comprises encapsulating at least a portion of the conductive bump.

13. The method of claim 10, wherein said encapsulating comprises encapsulating the top die surface and the side die surfaces.

14. The method of claim 10, wherein said forming an adhesive layer comprises applying an adhesive tape to the ground bottom surface of the wafer.

15. A semiconductor package comprising:
a semiconductor die having a top die surface, a bottom die surface and side die surfaces, and comprising a conductive bump on the top die surface;
a metal plate attached to the bottom die surface; and
an encapsulant that encapsulates the semiconductor die and a top surface of the metal plate.

16. The semiconductor package of claim 15, wherein the encapsulant encapsulates the die top surface and the side die surfaces.

17. The semiconductor package of claim 16, wherein the encapsulant encapsulates a portion of the conductive bump.

18. The semiconductor package of claim 15, wherein the metal plate comprises stainless steel.

19. The semiconductor package of claim 15, comprising an adhesive layer between the semiconductor die and the metal plate.

20. The semiconductor package of claim 19, wherein there is no adhesive layer between the metal plate and the encapsulant.
